(19) United States
(12) Patent Application Publication
(10) Pub. No.: US 2022/0056573 A1
(43) Pub. Date: Feb. 24, 2022

(54) MASK

(71) Applicant: KUNSHAN GO-VISIONOX OPTO-ELECTRONICS CO., LTD, Kunshan (CN)

(72) Inventors: Zhe LI, Kunshan (CN); Mingxing LIU, Kunshan (CN)

(73) Assignee: KUNSHAN GO-VISIONOX OPTO-ELECTRONICS CO., LTD, Kunshan (CN)

(21) Appl. No.: 17/516,032

(22) Filed: Nov. 1, 2021

Related U.S. Application Data
(63) Continuation of application No. PCT/CN2020/104348, filed on Jul. 24, 2020.

(30) Foreign Application Priority Data
Oct. 18, 2019 (CN) 201921754409.7

(51) Int. Cl. C23C 14/04; C23C 14/24; C23C 14/12

(52) U.S. Cl. CPC C23C 14/042; C23C 14/12; C23C 14/24

(57) ABSTRACT

A mask includes a plurality of opening areas and a shielding area surrounding the plurality of opening areas; the shielding area is provided with a plurality of grooves, and the plurality of grooves are symmetrical with respect to a symmetric line of the plurality of opening areas disposed in a same row.

### CROSS-REFERENCE TO RELATED APPLICATION(S)

This is a continuation of International Patent Application No. PCT/CN2020/104348, filed on Jul. 24, 2020, which claims priority to Chinese Patent Application No. 201921754409.7 filed with the CNIPA on Oct. 18, 2019, the disclosure of which is incorporated herein by reference in their entireties.

### FIELD

Embodiments of the present application relate to display technologies, for example, a mask.

### BACKGROUND

With the development of display technologies, the organic light-emitting display panel has been more and more widely used due to the advantages such as a high response range, high color purity, a wide viewing angle, foldability, and low energy consumption.

When the organic light-emitting display panel is manufactured, the evaporation technology is used such that the organic material is evaporated on a display substrate and thus an organic light-emitting layer is formed. This process requires the use of a mask. However, the mask in the related art has the problem of positional deviation of the opening, which affects the manufacturing accuracy of the display panel.

### SUMMARY

The present application provides a mask so that the accuracy of the opening position of the mask is improved, and thus the manufacturing accuracy of the display panel is improved.

Embodiments of the present application provide a mask.

The mask includes multiple opening areas and a shielding area surrounding the multiple opening areas.

The shielding area is provided with multiple grooves, and the multiple grooves are symmetrical with respect to a symmetric line of the multiple opening areas disposed in a same row.

In embodiments of the present application, the shielding area is provided with multiple grooves so that the difference in strength between the opening areas and the shielding area can be reduced, and the force between the opening areas and the shielding area can be balanced. Moreover, the multiple grooves are symmetrical with respect to the symmetric line of the multiple opening areas disposed in a same row so that the grooves of the mask are distributed more uniformly, and the stress distribution of the entire mask is more uniform. In this manner, the deformation of the mask during spreading and welding can be reduced so that the position accuracy of a pixel opening at the boundary of the opening areas of the mask can be improved, and thus the manufacturing accuracy of the display panel can be improved.

### BRIEF DESCRIPTION OF DRAWINGS

FIG. 1 is a structure diagram of a mask according to an embodiment of the present application;

FIG. 2A is a sectional diagram of the mask of FIG. 1 taken along an A-A cross-section according to an embodiment of the present application;

FIG. 2B is another sectional diagram of the mask of FIG. 1 taken along the A-A cross-section according to an embodiment of the present application;

FIG. 2C is another sectional diagram of the mask of FIG. 1 taken along the A-A cross-section according to an embodiment of the present application;

FIG. 2D is another sectional diagram of the mask of FIG. 1 taken along the A-A cross-section according to an embodiment of the present application;

FIG. 3A is a sectional diagram of the mask of FIG. 1 taken along a B-B cross-section according to an embodiment of the present application;

FIG. 3B is another sectional diagram of the mask of FIG. 1 taken along the B-B cross-section according to an embodiment of the present application;

FIG. 3C is another sectional diagram of the mask of FIG. 1 taken along the B-B cross-section according to an embodiment of the present application;

FIG. 3D is another sectional diagram of the mask of FIG. 1 taken along the B-B cross-section according to an embodiment of the present application; and

FIG. 4 is a sectional diagram of another mask according to an embodiment of the present application.

### DETAILED DESCRIPTION

The present application is described hereinafter in conjunction with drawings and embodiments. The embodiments described herein are intended to explain and not to limit the present application. In addition, for ease of description, only part, not all, of structures related to the present application are illustrated in the drawings.

As mentioned in the Background, the mask in the related art has the problem of positional deviation of the opening, which easily affects the manufacturing accuracy of the display panel. After research, it is found that the reason for this problem is that the mask is essentially a sheet metal with many very small through holes. During evaporation, the organic material rises after heating, and the organic material passing through the through holes of the mask is evaporated on the corresponding position of the display panel. Therefore, the position accuracy of the through holes on the mask determines the position accuracy of the evaporation material. In the related art, before evaporation, the mask is spread and welded to a mask frame. Before spreading and welding, a certain tensile force is applied to the mask so that the mask is prevented from sagging too much. However, due to the difference in strength between the through holes in the opening areas and the sheet metal in the shielding area of the mask, the force between the opening areas and the shielding area is not uniform so that the mask is deformed after spreading and welding, leading to the positional deviation of the opening at the boundary of the opening areas and the deviation of the evaporation position of the organic material, thereby affecting the manufacturing accuracy of the display panel.

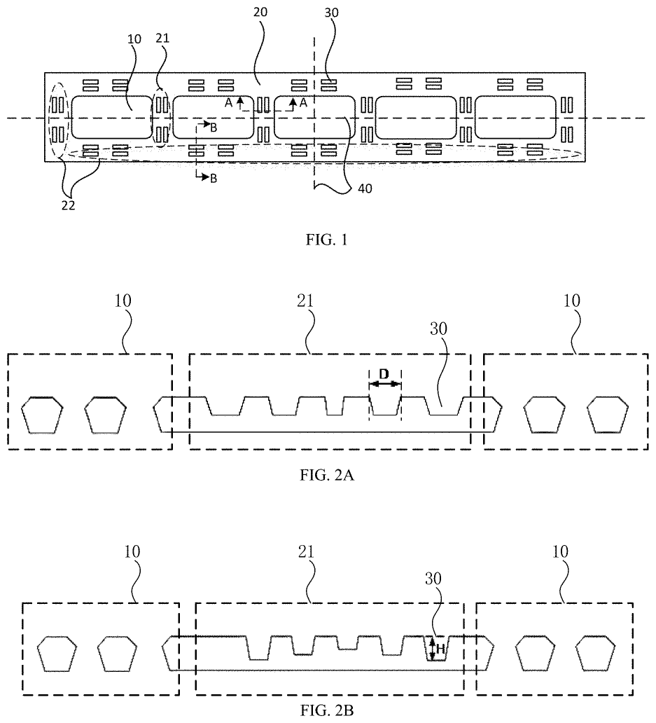

This embodiment provides a mask. FIG. 1 is a schematic diagram of a mask according to an embodiment of the present application. Referring to FIG. 1, the mask includes multiple opening areas 10 and a shielding area 20 surrounding the multiple opening areas 10; the shielding area 20 is provided with multiple grooves 30, and the multiple grooves 30 are symmetrical with respect to a symmetric line 40 of the multiple opening areas 10 disposed in a same row.

The opening areas 10 correspond to the display area of the display panel, each opening area 10 is provided with multiple pixel openings (referring to FIG. 4), and the evaporation material is evaporated on the corresponding pixel positions on a display substrate through the pixel openings. The shielding area 20 is an area through which the evaporation material cannot pass. The mask may be formed by using electroforming and/or etching processes, and the corresponding multiple grooves 30 may also be formed by using electroforming and/or etching processes. The etching process may include chemical etching and laser etching.

In this embodiment, the shielding area 20 is provided with multiple grooves 30 so that the difference in strength between the opening areas 10 and the shielding area 20 can be reduced, and the force between the opening areas 10 and the shielding area 20 can be balanced. Moreover, the multiple grooves 30 are symmetrical with respect to the symmetric line 40 of the multiple opening areas 10 disposed in a same row so that the grooves 30 of the mask are distributed more uniformly, and the stress distribution of the entire mask is more uniform. In this manner, the deformation of the mask during spreading and welding can be reduced so that the position accuracy of a pixel opening at the boundary of the opening areas 10 of the mask can be improved, and thus the manufacturing accuracy of the display panel can be improved.

FIG. 1 only exemplarily shows the number, shape, and position of the grooves 30 and exemplarily shows the number and position of the symmetric line 40. The number, shape, and position of grooves 30 can be set as required and multiple opening areas 10 may have one or more symmetric lines 40.

Optionally, multiple opening areas 10 disposed in a same row have at least two symmetric lines 40, and multiple grooves 30 are symmetrical with respect to any symmetric line 40 of the multiple opening areas 10 disposed in a same row.

In this manner, the grooves 30 of the mask are distributed more uniformly, and the stress distribution of the entire mask is more uniform so that the deformation of the mask during spreading and welding can be further reduced, the position accuracy of a pixel opening at the boundary of the opening areas 10 of the mask can be improved, and thus the manufacturing accuracy of the display panel can be improved.

The mask may be an ordinary mask or a precision metal mask. Optionally, the mask is a precision metal mask.

Optionally, referring to FIG. 1, the shielding area 20 includes a first shielding area 21 and a second shielding area 22. The first shielding area 21 is an area between adjacent opening areas 10, and the second shielding area 22 is an area between the opening areas 10 and the edge of the mask; the first shielding area 21 and the second shielding area 22 are both provided with multiple grooves 30.

The first shielding area 21 and the second shielding area 22 are both provided with multiple grooves 30. In this manner, not only the difference in strength between the shielding area 20 between the opening areas 10 and the opening areas 10 can be reduced, but also the difference in strength between the shielding area 20 between the opening areas 10 and the edge of the mask, and the opening areas 10 can be reduced. That is, the difference in strength between the opening areas 10 and all the shielding areas 20 of the mask can be reduced so that the force between the opening areas 10 and the shielding area 20 can be further balanced, the stress distribution of the entire mask is more uniform, and thus the deformation of the mask during spreading and welding can be further reduced. In an embodiment, the weight of the mask can also be reduced, and the deformation of the mask during spreading and welding can be further reduced.

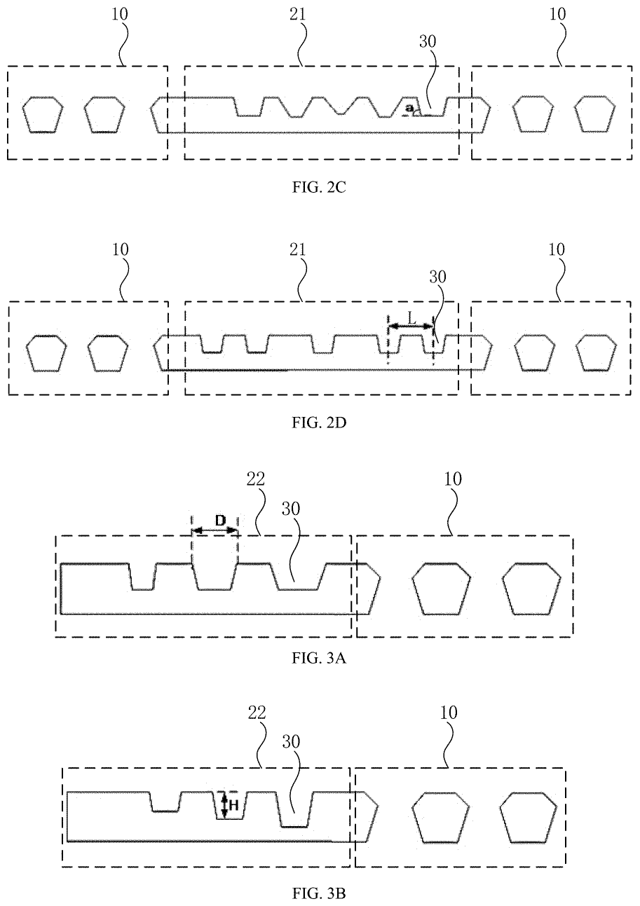

FIG. 2A is a sectional diagram of the mask of FIG. 1 taken along an A-A cross-section according to an embodiment of the present application; FIG. 2B is another sectional diagram of the mask of FIG. 1 taken along the A-A cross-section according to an embodiment of the present application; FIG. 2C is another sectional diagram of the mask of FIG. 1 taken along the A-A cross-section according to an embodiment of the present application; and FIG. 2D is another sectional diagram of the mask of FIG. 1 taken along the A-A cross-section according to an embodiment of the present application. Optionally, referring to FIGS. 2A to 2D, in the first shielding area 21, along a direction from one opening area 10 to another opening area 10, at least one of an opening size D of the groove 30, a depth H of the groove 30, or a gradient a of the groove 30 changes from great to small and then to great.

The opening size D of the groove 30 is the maximum size of the groove 30 along a direction parallel to the surface of the mask. Exemplarily, the opening size D of the groove 30 may be the maximum size of the groove 30 on the plane where the surface of the mask is located. The gradient a of the groove 30 is the angle between the side surface and the bottom surface of the groove 30. The depth H of the groove 30 is the size of the groove 30 along the thickness direction of the mask.

In the first shielding area 21, along the direction from one opening area 10 to another opening area 10, at least one of the opening size D of the groove 30, the depth H of the groove 30, or the gradient a of the groove 30 changes from great to small and then to great. In this manner, the following case can be avoided: the size, depth, or gradient occupied by multiple grooves 30 in the first shielding area 21 is too great so that the structural strength of the first shielding area 21 is too small; and at the same time, the following case can be avoided: the area, depth, or gradient occupied by multiple grooves 30 is too small, the differences between the size, depth, or gradient of the multiple grooves 30 and the size, depth, or gradient of the pixel openings of the opening areas 10 are too great, and the balance effect on the first shielding area 21 and the opening areas 10 is too small so that the uniform transition of the first shielding area 21 to the opening areas 10 located on two sides of the first shielding area 21 is ensured, the difference in strength between the opening area 10 and the first shielding area 21 can be better reduced, and thus the stress distribution is more uniform, and the deformation of the mask during spreading and welding can be reduced.

A center line in the first shielding area 21 may be taken as a dividing line, where the distance between the center line and one of two opening areas 10 adjacent to the first shielding area 21 is same as the distance between the center line and the other one of the two opening areas 10 adjacent to the first shielding area 21. Along a direction from one opening area 10 to the center line, at least one of the opening size D of the groove 30, the depth H of the groove 30, or the gradient a of the groove 30 changes from great to small. Along a direction from the center line to the other opening area 10, at least one of the opening size D of the groove 30, the depth H of the groove 30, or the gradient a of the groove 30 changes from small to great.

Optionally, referring to FIG. 2D, in the first shielding area 21, along a direction from one opening area 10 to the other opening area 10, the spacing L of the grooves 30 changes from small to great and then to small. In this manner, the uniform transition of the first shielding area 21 to the opening areas 10 located on two sides of the first shielding area 21 is further ensured, and the difference in strength between the opening areas 10 and the first shielding area 21 can be better reduced so that the stress distribution is more uniform, and the deformation of the mask during spreading and welding can be reduced.

The spacing L of the grooves 30 is the distance between the centers of two adjacent grooves 30.

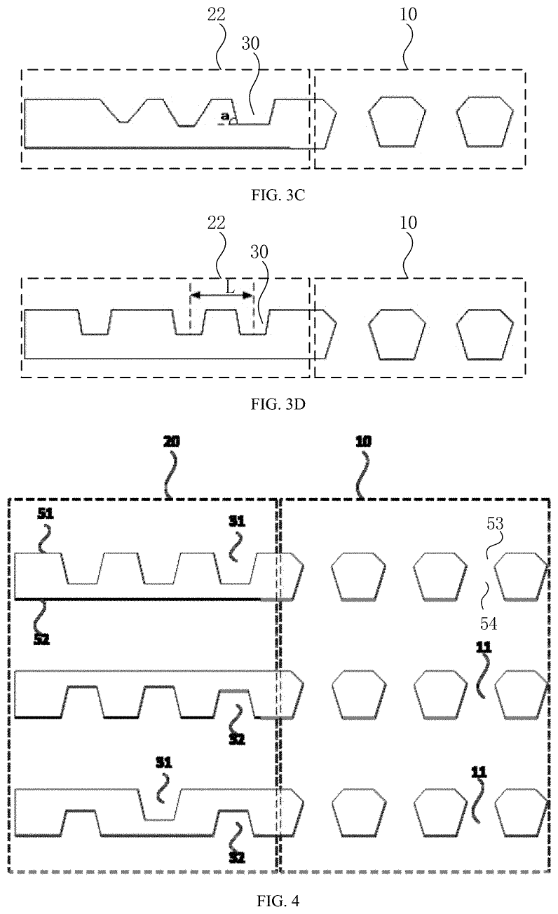

FIG. 3A is a sectional diagram of the mask of FIG. 1 taken along a B-B cross-section according to an embodiment of the present application; FIG. 3B is another sectional diagram of the mask of FIG. 1 taken along the B-B cross-section according to an embodiment of the present application; FIG. 3C is another sectional diagram of the mask of FIG. 1 taken along the B-B cross-section according to an embodiment of the present application; and FIG. 3D is another sectional diagram of the mask of FIG. 1 taken along the B-B cross-section according to an embodiment of the present application. Optionally, referring to FIGS. 3A to 3D, in the second shielding area 22, along a direction from the opening area 10 to the edge of the mask, at least one of the opening size D of the groove 30, the depth H of the groove 30, or the gradient a of the groove 30 changes from great to small.

In the second shielding area 22, along the direction from the opening area 10 to the edge of the mask, the spacing L of the grooves 30 changes from small to great.

In this manner, along the direction from the opening area 10 to the edge of the mask, the shape transition of the second shielding area 22 is smoother so that the stress distribution is more uniform, and thus the deformation of the mask during spreading and welding can be further reduced.

FIG. 4 is a sectional diagram of another mask according to an embodiment of the present application. Optionally, referring to FIG. 4, the mask includes a first surface 51 and a second surface 52 that are opposite to each other; in the shielding area 20, the first surface 51 is provided with multiple first grooves 31, and/or the second surface 52 is provided with multiple second grooves 32. Referring to FIG. 4, in an embodiment, each opening area 10 includes multiple pixel openings 11, the first surface 51 is provided with multiple third grooves 53, the second surface 52 is provided with multiple fourth grooves 54, the multiple third grooves 53 and the multiple fourth grooves 54 are in a one-to-one correspondence, and each pixel opening 11 is formed by one third groove 53 and one fourth groove 54 communicating with each other.

In the case where the pixel openings 11 in the opening area 10 are formed, the third grooves 53 are formed by etching on the first surface 51, the fourth grooves 54 are formed by etching on the second surface 52, the third grooves and the fourth grooves are in a one-to-one correspondence, and one set of one third groove and one fourth groove forms one pixel opening 11 which extends through the mask.

The first grooves 31 and the third grooves 53 of the first surface 51 may be formed in the same process by using the same mask, and the second grooves 32 and the fourth grooves 54 of the second surface 52 may be formed in the same process by using the same mask. Therefore, the provision of the first grooves 31 on the first surface 51 and the provision of the second grooves 32 on the second surface 52 do not increase the number of masks so that it is ensured that the manufacturing cost of the mask is relatively low. In the case where only the first grooves 31 are provided on the first surface 51 or only the second grooves 32 are provided on the second surface 52, only the number of openings of one mask (the mask used in the case where the third grooves 53 are formed or the mask used in the case where the fourth grooves 54 are formed) needs to be changed. In this manner, while the difference in strength between the opening area 10 and the shielding area 20 is reduced, the cost can be further reduced.

Since the pixel opening 11 is in the form of a through hole, in the case where the first surface 51 is provided with the first grooves 31 and the second surface 52 is provided with the second grooves 32, the difference in strength between the shielding area 20 on the first surface 51 and the opening area 10 and the difference in strength between the shielding area 20 on the second surface 52 and the opening area 10 may be better balanced at the same time so that the stress distribution on the first surface 51 and the second surface 52 is more uniform, and the deformation of the mask during spreading can be further reduced.

The first surface 51 may be a glass surface of the mask, that is, the surface of the mask facing a display substrate to be evaporated. The second surface 52 may be an evaporation surface, that is, the surface of the mask facing an evaporation source.

Optionally, the first grooves 31 and the second grooves 32 are alternately arranged, and the vertical projections of the first grooves 31 on the mask and the vertical projections of the second grooves 32 on the mask do not overlap.

The first grooves 31 and the second grooves 32 are alternately arranged so that the groove distribution of the first surface 51 is similar to the groove distribution of the second surface 52, and thus it is ensured that the difference in strength between the first surface 51 and the second surface 52 is relatively small and the stress distribution of the entire mask is more uniform. Moreover, since the thickness of the mask at the overlapping position of the first groove 31 and the second groove 32 is relatively thin, the strength is relatively weak, and stress concentration easily occurs. The vertical projections of the first grooves 31 on the mask and the vertical projections of the second grooves 32 on the mask do not overlap so that stress concentration can be avoided, and it is ensured that the mask has a relatively high structural strength.

Optionally, the depth H of the groove 30 is less than or equal to four-fifths of the thickness of the mask.

The opening area 10 includes multiple pixel openings 11. The opening size D of the groove 30 is less than or equal to the opening size of the pixel opening 11; the spacing L of the grooves 30 is greater than or equal to the opening spacing of the pixel openings 11; the gradient a of the groove 30 is less than or equal to the opening gradient of the pixel opening 11.

In this manner, the following case can be avoided: the area, depth, or gradient occupied by the groove of the shielding area 20 is too great, and the spacing L of the grooves 30 is too small so that the structural strength of the shielding area 20 is too small; it is ensured that the mask has a relatively high structural strength; at the same time, the difference in strength between the shielding area 20 and the opening area 10 can be better balanced; therefore, the stress distribution is more uniform, and the deformation of the mask during spreading can be reduced.

The depth H of the groove 30, the opening size D of the groove 30, the spacing L of the grooves 30, and the gradient a of the groove 30 can be set according to the requirements for the stress distribution of the mask. Exemplarily, the depth H of the groove 30 may be set to be less than or equal to two-thirds or one-half of the thickness of the mask.

Optionally, the shape of the cross-section of the groove perpendicular to the mask is trapezoidal or rectangular.

The shape of the cross-section of the groove 30 perpendicular to the mask may be set according to the shape of the cross-section of the pixel opening 11 perpendicular to the mask in the opening area 10. The shape of the cross-section of the groove 30 perpendicular to the mask may be same as the shape of the cross-section of the pixel opening 11 perpendicular to the mask in the opening area 10 so that the difference in strength between the shielding area 20 and the opening area 10 can be better reduced. Exemplarily, the shape of the cross-section, perpendicular to the mask, of the first groove 31 provided on the first surface 51 may be same as the shape of the cross-section of the pixel opening 11 perpendicular to the mask on the side of the first surface 51, and the shape of the cross-section, perpendicular to the mask, of the second groove 32 provided on the second surface 52 may be same as the shape of the cross-section of the pixel opening 11 perpendicular to the mask on the side of the second surface 52, that is, the shape of the cross-section of the first groove 31 perpendicular to the mask may be same as the shape of the cross-section of the third groove 53 perpendicular to the mask, and the shape of the cross-section of the second groove 32 perpendicular to the mask may be same as the shape of the cross-section of the fourth groove 54 perpendicular to the mask.

The shape of the cross-section of the groove parallel to the first surface 51 or the second surface 52 may be same as or different from the shape of the cross-section of the pixel opening 11 parallel to the first surface 51 or the second surface 52, which can be set according to the requirements for the stress distribution. For example, the shape of the cross-section of the first groove 31 parallel to the first surface 51 and the shape of the cross-section of the second groove 32 parallel to the first surface 51 are the same or different from the shape of the cross-section of the pixel opening parallel to the first surface 51. Exemplarily, the shape of the cross-section of the groove parallel to the first surface 51 or the second surface 52 may be circular, rectangular, or square. For example, the shape of the cross-section of the first groove 31 parallel to the first surface 51 and the shape of the cross-section of the second groove 32 parallel to the first surface 51 are circular, rectangular, or square.

What is claimed is:

1. A mask, comprising:
a plurality of opening areas and a shielding area surrounding the plurality of opening areas,
wherein the shielding area is provided with a plurality of grooves, and the plurality of grooves are symmetrical with respect to a symmetric line of the plurality of opening areas disposed in a same row.

2. The mask of claim 1, wherein
the shielding area comprises a first shielding area and a second shielding area, wherein the first shielding area is an area between adjacent ones of the plurality of opening areas, and the second shielding area is an area between the plurality of opening areas and an edge of the mask; and
the first shielding area and the second shielding area are provided with the plurality of grooves respectively.

3. The mask of claim 2, wherein
in the first shielding area, along a direction from one of the plurality of opening areas to another one of the plurality of opening areas, at least one of an opening size of each of the plurality of grooves, a depth of each of the plurality of grooves, or a gradient of each of the plurality of grooves changes from great to small and then to great; and
in the second shielding area, along a direction from one of the plurality of opening areas to the edge of the mask, at least one of an opening size of each of the plurality of grooves, a depth of each of the plurality of grooves, or a gradient of each of the plurality of grooves changes from great to small.

4. The mask of claim 2, wherein
in the first shielding area, along a direction from one of the plurality of opening areas to another one of the plurality of opening areas, a spacing of the plurality of grooves changes from small to great and then to small; and
in the second shielding area, along a direction from one of the plurality of opening areas to the edge of the mask, a spacing of the plurality of grooves changes from small to great.

5. The mask of claim 1, wherein
the mask comprises a first surface and a second surface that are opposite to each other; and
in the shielding area, the plurality of grooves comprise a plurality of first grooves, the first surface is provided with the plurality of first grooves; or, in the shielding area, the plurality of grooves comprise a plurality of second grooves, the second surface is provided with the plurality of second grooves; or, in the shielding area, the plurality of grooves comprise a plurality of first grooves and a plurality of second grooves, the first surface is provided with the plurality of first grooves and the second surface is provided with the plurality of second grooves.

6. The mask of claim 5, wherein
in the shielding area, the first surface is provided with the plurality of first grooves and the second surface is provided with the plurality of second grooves;
the plurality of first grooves and the plurality of second grooves are alternately arranged, and vertical projections of the plurality of first grooves on the mask and vertical projections of the plurality of second grooves on the mask do not overlap.

7. The mask of claim 5, wherein
each of the plurality of opening areas comprises a plurality of pixel openings, the first surface is provided with a plurality of third grooves, the second surface is provided with a plurality of fourth grooves, the plurality of third grooves and the plurality of fourth grooves are in a one-to-one correspondence, and each of the plurality of pixel openings is formed by one of the plurality of third grooves and one of the plurality of fourth grooves communicating with each other.

8. The mask of claim 7, wherein each of the plurality of third grooves is formed by etching on the first surface, and each of the plurality of fourth grooves is formed by etching on the second surface.

9. The mask of claim 5, wherein
the first surface is a glass surface of the mask, and the second surface is an evaporation surface.

10. The mask of claim 1, wherein
a depth of each of the plurality of grooves is less than or equal to four-fifths of a thickness of the mask.

11. The mask of claim 1, wherein
each of the plurality of opening areas comprises a plurality of pixel openings, and an opening size of each of the plurality of grooves is less than or equal to an opening size of each of the plurality of pixel openings;
a spacing of the plurality of grooves is greater than or equal to an opening spacing of the plurality of pixel openings; and
a gradient of each of the plurality of grooves is less than or equal to an opening gradient of each of the plurality of pixel openings.

12. The mask of claim 1, wherein
the mask has at least two symmetric lines, and the plurality of grooves are symmetrical with respect to any one of the at least two symmetric lines of the plurality of opening areas disposed in a same row.

13. The mask of claim 1, wherein
a shape of a cross-section of each of the plurality of grooves perpendicular to the mask is trapezoidal or rectangular.

14. The mask of claim 11, wherein a shape of a cross-section of each of the plurality of grooves perpendicular to the mask is same as a shape of a cross-section of each of the plurality of pixel openings perpendicular to the mask.

15. The mask of claim 7, wherein a shape of a cross-section of each of the plurality of first grooves perpendicular to the mask is same as a shape of a cross-section of each of the plurality of third grooves perpendicular to the mask; a shape of a cross-section of each of the plurality of second grooves perpendicular to the mask is same as a shape of a cross-section of each of the plurality of fourth grooves perpendicular to the mask.

16. The mask of claim 7, wherein
a shape of a cross-section of each of the plurality of first grooves parallel to the first surface and a shape of a cross-section of each of the plurality of second grooves parallel to the first surface are both same as a shape of a cross-section of each of the plurality of pixel openings parallel to the first surface.

17. The mask of claim 7, wherein
a shape of a cross-section of each of the plurality of first grooves parallel to the first surface and a shape of a cross-section of each of the plurality of second grooves parallel to the first surface are both different from a shape of a cross-section of each of the plurality of pixel openings parallel to the first surface.

18. The mask of claim 16, wherein
the shape of the cross-section of each of the plurality of first grooves parallel to the first surface and the shape of the cross-section of each of the plurality of second grooves parallel to the first surface are both circular, rectangular, or square.

19. The mask of claim 1, wherein
the mask is a precision metal mask.

20. The mask of claim 10, wherein the depth of each of the plurality of grooves is less than or equal to two-thirds the thickness of the mask.
